(19) United States
(12) Patent Application Publication
(10) Pub. No.: US 2019/0152782 A1
(43) Pub. Date: May 23, 2019

(54) Solid Carbon Nanotube Forests and Methods for Producing Solid Carbon Nanotube Forests

(71) Applicant: Seerstone LLC, Provo, UT (US)

(72) Inventors: Dallas B. Noyes, Provo, UT (US); Anthony C. Pearson, Provo, UT (US)

(73) Assignee: Seerstone LLC, Provo, UT (US)

(21) Appl. No.: 16/320,640

(22) PCT Filed: Jul. 28, 2016
(86) PCT No.: PCT/US2017/044498

§ 371 Date: Jan. 25, 2019

Related U.S. Application Data
(60) Provisional application No. 62/367,993, filed on Jul. 28, 2016.

(51) Int. Cl. C01B 32/162; B01J 21/04; B01J 23/745; B01J 35/00; B01J 37/02; B01J 37/18; C23C 16/26; C23C 16/02

(52) U.S. Cl. CPC C01B 32/162; B01J 21/04; B01J 23/745; B01J 35/0013; B01J 37/0244; C01P 2004/03; B01J 37/0228; B01J 37/18; C23C 16/26; C23C 16/0281; B01J 37/0225

(57) ABSTRACT

A method of producing forests of fibrous solid carbon includes providing a catalyst material over a substrate, forming the catalyst material into catalyst nanoparticles, and reacting carbon monoxide with hydrogen in the presence of the catalyst nanoparticles to form forests of fibrous solid carbon attached to the catalyst nanoparticles. A composition of matter includes an inert material disposed upon a substrate, a plurality of nanoparticles of catalyst material upon the inert material, and a plurality of carbon nanotubes upon the nanoparticles. Some methods of producing a forest of carbon nanotubes include preparing a catalyst surface by depositing an inert material onto stainless steel, and depositing iron onto the inert material. The catalyst surface is placed into a furnace chamber, and the furnace chamber is heated. A mixture of hydrogen and carbon monoxide is provided into the furnace chamber

### PRIORITY CLAIM

This application claims the benefit under 35 U.S.C. § 119(e) and Article 8 of the PCT to U.S. Provisional Patent Application Ser. No. 62/367,993, filed Jul. 28, 2016, for “SOLID CARBON NANOTUBE FORESTS AND METHODS FOR PRODUCING SOLID CARBON NANOTUBE FORESTS” the contents of which are incorporated by this reference.

### FIELD

Embodiments of the disclosure relate to the catalytic conversion of a carbon-containing feedstock into solid carbon and more specifically, to methods of converting mixtures of carbon monoxide and hydrogen to create nanostructured carbon.

BACKGROUND

Solid carbon has numerous commercial applications. For example, carbon black and carbon fibers may be used as a filler material in tires, inks, etc. Various forms of graphite have known uses, (e.g., pyrolytic graphite as heat shields) and innovative and emerging applications are being developed for buckminsterfullerene (including “buckyballs” and “buckytubes”). Conventional methods for the manufacture of various forms of solid carbon typically involve the pyrolysis of hydrocarbons in the presence of a suitable catalyst. Hydrocarbons are typically used as the carbon source due to abundant availability and relatively low cost. The use of carbon oxides as the carbon source in reduction reactors for the production of solid carbon has largely been unexploited.

Carbon oxides, particularly carbon dioxide, are abundant gases that may be extracted from point-source emissions such as the exhaust gases of hydrocarbon combustion or from some process off-gases. Carbon dioxide may also be extracted from the air. Because point-source emissions have much higher concentrations of carbon dioxide than does ambient air, they are often economical sources from which to harvest carbon dioxide. However, the immediate availability of air may provide cost offsets by eliminating transportation costs through manufacturing of solid carbon products from carbon dioxide in air at any selected location.

Carbon dioxide is increasingly available and inexpensive as a byproduct of power generation and chemical processes in which an object is to reduce or eliminate the emission of carbon dioxide into the atmosphere by capture and subsequent sequestration of the carbon dioxide (e.g., by injection into a geological formation). For example, the capture and sequestration of carbon dioxide is the basis for some “green” coal-fired power stations. Capture and sequestration of the carbon dioxide typically entails significant cost.

There is a spectrum of reactions involving carbon, oxygen, and hydrogen wherein various equilibria have been identified. Hydrocarbon pyrolysis involves equilibria between hydrogen and carbon that favor solid carbon production, typically with little or no oxygen present. The Boudouard reaction, also called the carbon monoxide disproportionation reaction, occurs in the range of equilibria between carbon and oxygen that favors solid carbon production, typically with little or no hydrogen present. The Bosch reaction occurs within a region of equilibria where all of carbon, oxygen, and hydrogen are present under reaction conditions that also favor solid carbon production.

The relationship between the hydrocarbon-pyrolysis, Boudouard, and Bosch reactions may be understood in terms of a C—H—O equilibrium diagram, as shown in FIG. 1. The C—H—O equilibrium diagram of FIG. 1 shows various known routes to solid carbon, including carbon nanotubes (“CNTs”) and carbon nanofibers. Hydrocarbon-pyrolysis reactions occur on the equilibrium line that connects H and C and in the region near the left edge of the triangle to the upper left of the dashed lines. Two dashed lines are shown because the transition between the pyrolysis zone and the Bosch reaction zone appears to change with temperature. Boudouard reactions occur near the equilibrium line that connects O and C (i.e., the right edge of the triangle). The equilibrium lines for various temperatures that traverse the diagram show the approximate regions in which solid carbon will form. For each temperature, solid carbon generally forms in the regions above the associated equilibrium line, but will not generally form in the regions below the equilibrium line. The Boudouard reaction zone appears at the right side of the triangle. In this zone, the Boudouard reaction is thermodynamically preferred over the Bosch reaction. In the region between the pyrolysis zone and the Boudouard reaction zone and above a particular reaction temperature curve, the Bosch reaction is thermodynamically preferred over the Boudouard reaction.

CNTs and carbon nanofibers are valuable because of their unique material properties, including strength, current-carrying capacity, and thermal and electrical conductivity. Current bulk use of CNTs includes use as an additive to resins in the manufacture of composites. Research and development on the applications of CNTs is very active with a wide variety of applications in use or under consideration. One obstacle to widespread use of CNTs has been the cost of manufacture.

U.S. Pat. No. 7,794,690 (Abatzoglou et al.) teaches a dry reforming process for sequestration of carbon from an organic material. Abatzoglou discloses a process utilizing a 2-D carbon sequestration catalyst with, optionally, a 3-D dry reforming catalyst. For example, Abatzoglou discloses a two-stage process for dry reformation of an organic material (e.g., methane, ethanol) and CO₂ over a 3-D catalyst to form syngas, in a first stage, followed by carbon sequestration of syngas over a 2-D carbon steel catalyst to form CNTs and carbon nanofilaments. The 2-D catalyst may be an active metal (e.g., Ni, Rh, Ru, Cu—Ni, Sn—Ni) on a nonporous metallic or ceramic support, or an iron-based catalyst (e.g., steel), on a monolith support. The 3-D catalyst may be of similar composition, or may be a composite catalyst (e.g., Ni/ZrO₂—Al₂O₃) over a similar support. Abatzoglou teaches preactivation of a 2-D catalyst by passing an inert gas stream over a surface of the catalyst at a temperature beyond its eutectic point, to transform the iron into its alpha phase. Abatzoglou teaches minimizing water in the two-stage process or introducing water in low concentrations (0 to 10 wt %) in a reactant gas mixture during the dry reformation first stage.

Catalysts can be formed from the decomposition of catalyst precursors. For example, supported catalysts are often prepared by combining precursors of the catalyst material to be formed with a particulate catalyst support. Suitable precursors include compounds that combust to form oxides. For example, if iron is desired as a catalyst, suitable precursors may include iron (III) nitrate, iron sulfite, iron sulfate, iron carbonate, iron acetate, iron citrate, iron gluconate, and iron oxalate. In order to control the diameter of solid carbon nanotube products formed on such catalysts, the metal loading on the catalyst support may be controlled. Such methods generally include removing the catalyst support from the catalyst and solid carbon nanotube product after completion of the reaction.

The catalyst support and catalyst preparation methods currently known in the art are time consuming and costly. Often, reactors must be designed to accommodate the use of catalysts and catalyst supports created through such methods. One obstacle to the widespread use of carbon nanotubes has been the complexity and cost of manufacture.

### DISCLOSURE

In some embodiments, a method of producing forests of fibrous solid carbon includes providing a catalyst material over a substrate, forming catalyst nanoparticles from the catalyst material, and reacting carbon monoxide with hydrogen in the presence of the catalyst nanoparticles to form forests of fibrous solid carbon attached to the catalyst nanoparticles. A composition of matter includes an inert material on a substrate, a plurality of catalyst nanoparticles over the inert material, and a plurality of particles of fibrous solid carbon attached to the catalyst nanoparticles.

In other embodiments, a method includes depositing an inert material onto a stainless steel sheet, and depositing iron onto the inert material. The stainless steel sheet is heated in a furnace chamber, and a mixture of hydrogen and carbon monoxide is provided into the furnace chamber to form a forest of fibrous carbon nanoparticles on the iron.

### BRIEF DESCRIPTION OF THE DRAWINGS

FIG. 1 depicts a C—H—O equilibrium diagram.

FIGS. 2A through 2C are simplified schematic diagrams illustrating substrates upon which solid carbon may be formed and a method of preparing substrates and forming solid carbon.

FIGS. 3A through 3C are scanning electron microscope (SEM) images of a forest of CNTs at various magnifications.

FIGS. 4 through 73 are SEM images of solid carbon at various magnifications produced as described in Examples 1 through 11.

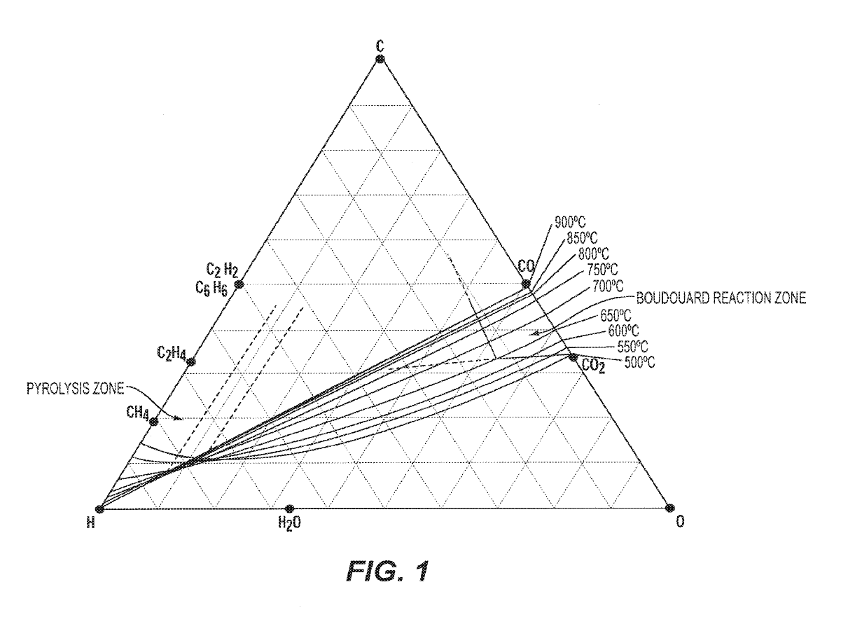

### MODE(S) FOR CARRYING OUT THE INVENTION

This disclosure includes methods for forming solid carbon products, such as generally aligned fibrous CNT and carbon nanofiber forests, from carbon monoxide and hydrogen. The carbon monoxide may be a product of combustion of a primary hydrocarbon or from some other source. The reaction occurs in the presence of a catalyst.

Efficient, industrial-scale production of solid carbon products may be performed using carbon monoxide as a carbon source and hydrogen as a reducing agent. The type (e.g., morphology), purity, and homogeneity of the solid carbon product are typically controlled by controlling the reaction time, temperature and pressure of the reactor, the concentrations of various gases in the reactor, the size and method of formation of the catalyst, the chemical composition of the catalyst, and the form and shape of the catalyst. The methods are particularly useful for the formation of carbon nanotubes and nanofibers that grow substantially perpendicular to the catalyst surface and substantially parallel to each other.

One of the solid carbon morphologies of particular note is carbon forests or clusters. The terms “carbon forest” and “forest,” as used herein, refer to a group of carbon nanotubes or nanofibers substantially perpendicular to a catalyst surface and substantially parallel to each other. The carbon forests may also be substantially integrated, and individual nanotubes or nanofibers may cross and intertwine with each other as the nanotubes or nanofibers protrude from the catalyst surface. In some embodiments, the nanotubes or nanofibers may have substantially uniform lengths and/or diameters. For example, the nanotubes or nanofibers of a carbon forest may each have lengths between about 95% and 105% of the median length of the nanotubes or nanofibers. In some embodiments, the nanotubes or nanofibers of a carbon forest may each have diameters between about 95% and 105% of the median diameter of the nanotubes or nanofibers.

As used herein, the term “carbon nanofiber” means and includes a carbon-containing material comprising a solid generally cylindrical shape substantially free of any voids (e.g., without a hollow central portion). A carbon nanofiber may be similar to a CNT, but may include a solid core rather than a hollow central portion. Carbon nanofibers may exhibit a rod-like shape and may exhibit a greater density than CNTs. In some embodiments, carbon nanofibers may exhibit a greater density than CNTs having the same diameter. Carbon nanofibers may also be in the form of stacked graphene sheets.

The reaction conditions, including the temperature and pressure in the reaction zone, the residence time of the reaction gases, and the grain size, grain boundary, and chemical composition of the catalyst, may be controlled to obtain forests having selected characteristics including mean diameter and length of the fibers.

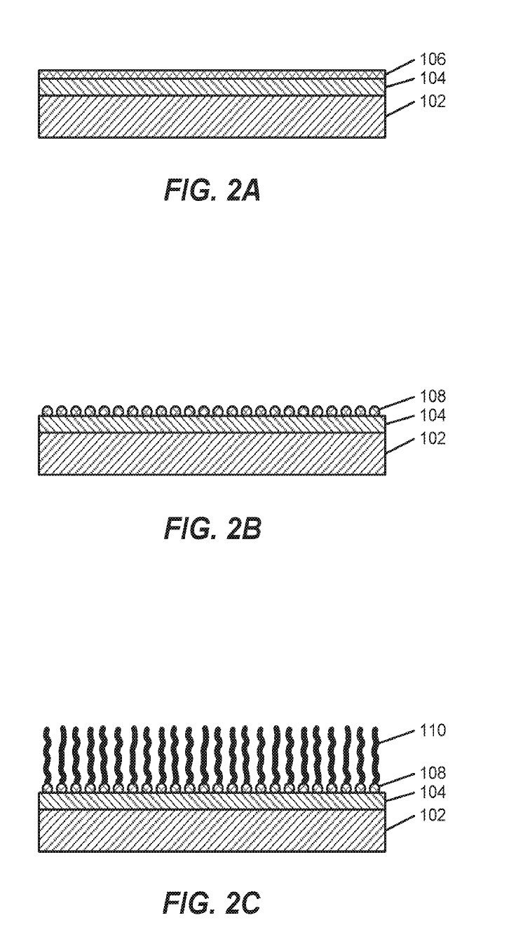

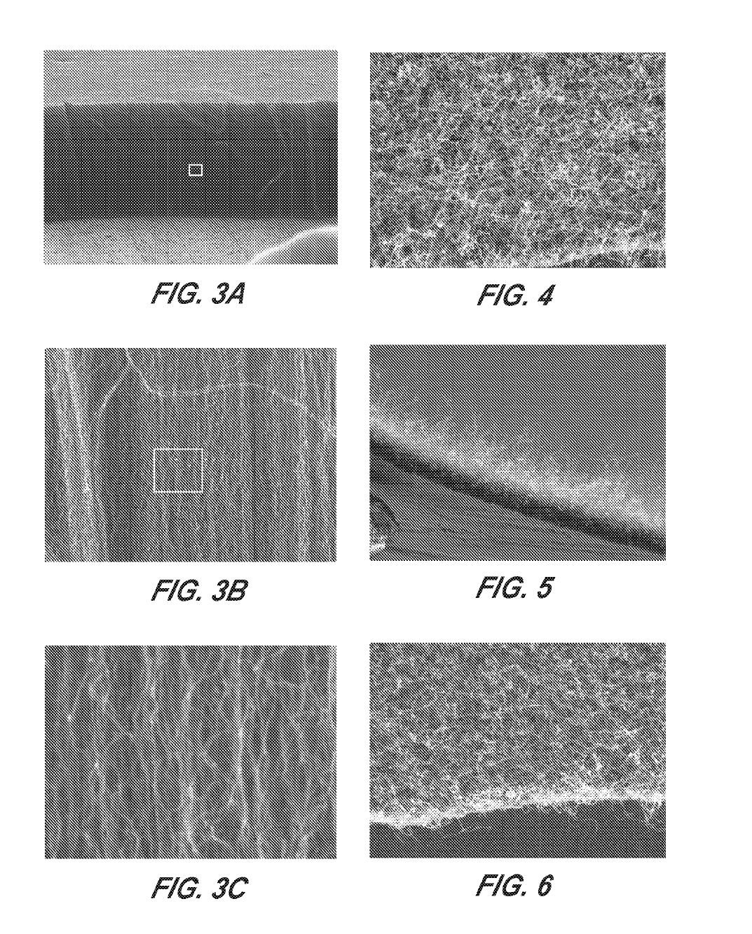

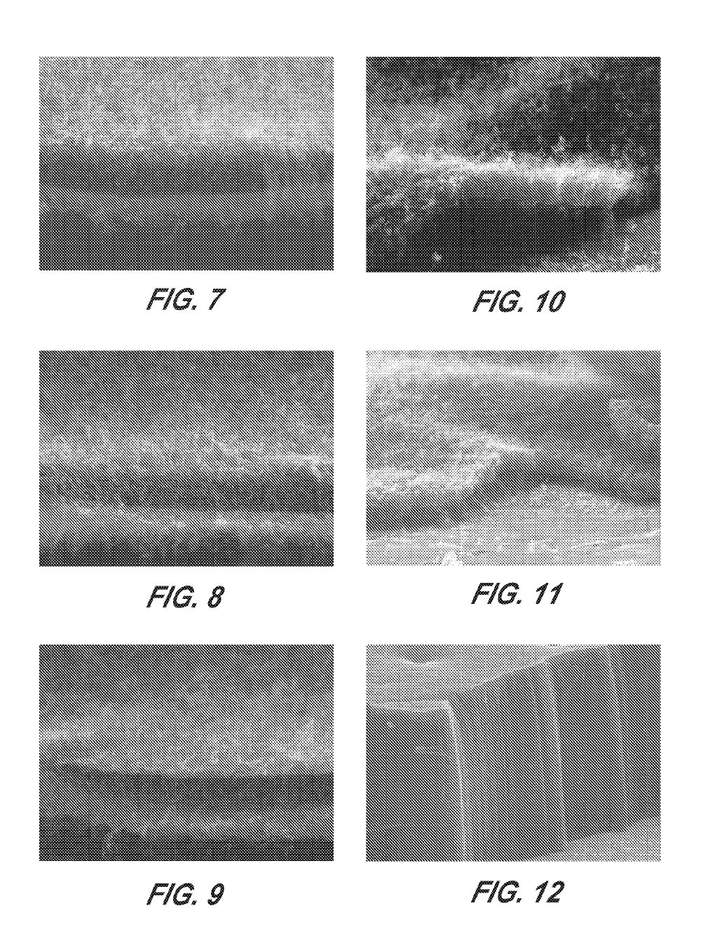

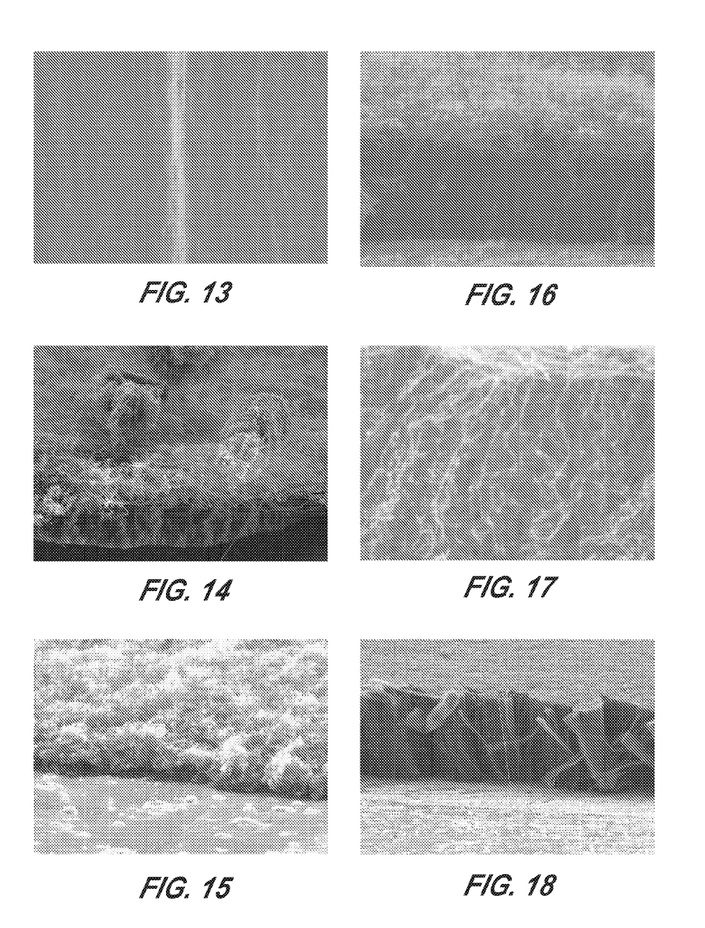

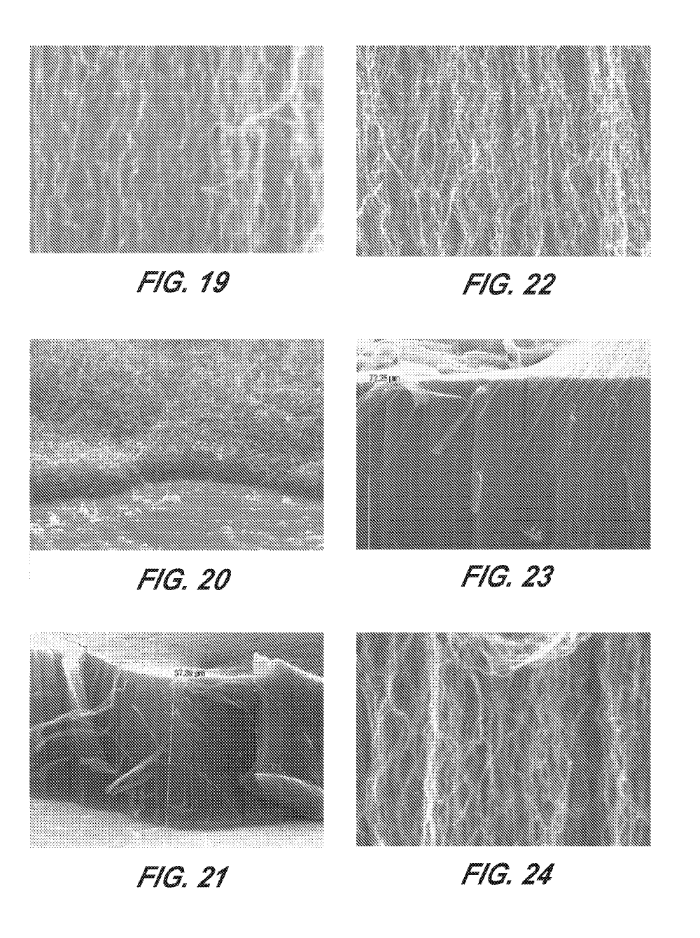

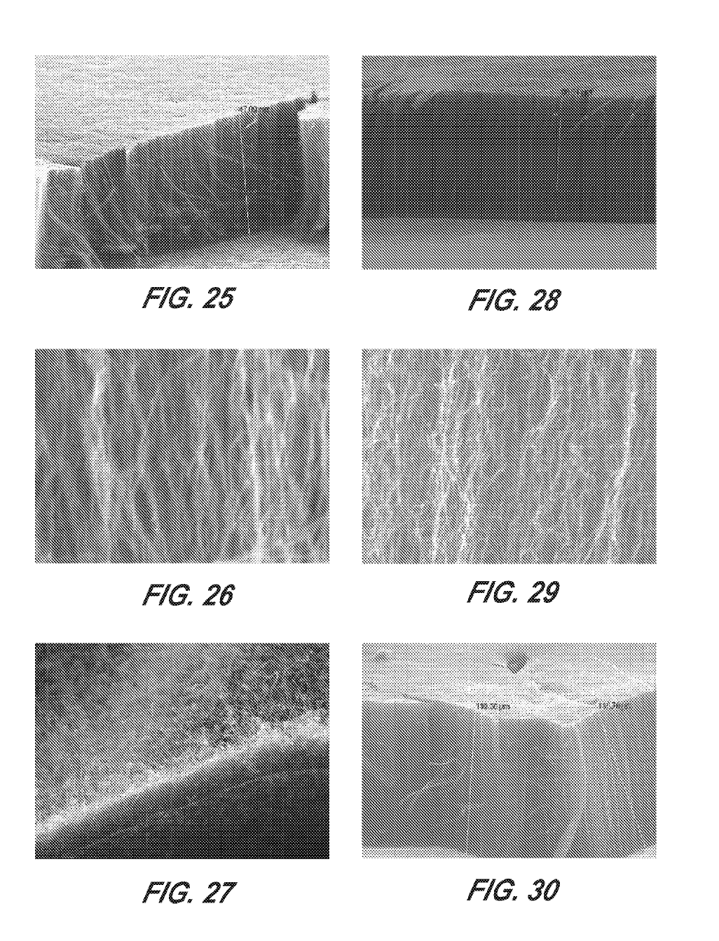

Carbon forests may be formed, for example, as shown in FIGS. 2A through 2C. FIG. 2A is a simplified schematic diagram illustrating a substrate 102, over which an inert material 104 and a catalyst 106 are formed. The substrate 102 may include one or more materials formulated to provide structure to the catalyst 106, such as a metal (e.g., a relatively pure metal, an alloy, an oxide, etc.), a ceramic, a glass such as quartz, etc. The substrate 102 may be configured as a sheet of foil, a bar, a rod, a hollow cylinder, etc., of any selected dimensions. In some embodiments, the substrate 102 is a sheet (e.g., foil) of stainless steel, such as 304L stainless steel, which may be used in a commercially available configuration (e.g., length, width, thickness, composition, roughness, etc., as available on the commercial or industrial market). The substrate 102 may be formulated to be unreactive under the conditions of the process or may be formulated to be less reactive than the catalyst 106. In some embodiments, the substrate 102 may include silicon, a metal, a ceramic, graphite, or any material on which solid carbon does not readily form. In some embodiments, the substrate 102 may itself be a material that catalyzes carbon deposition (in which case the inert material 104 may separate the substrate 102 from the catalyst 106 on which carbon is to be deposited), and may prevent deposition of carbon directly on the substrate 102.

The inert material 104 may be deposited conformally over the substrate 102, such as by conventional thin-film deposition techniques (e.g., electroplating, coating, physical vapor deposition, chemical vapor deposition, sputtering, etc.). In some embodiments, the inert material 104 may be formed by casting, spraying a solution of inert material, or other methods. The inert material 104 may be any material formulated to be unreactive with the reaction gases to be used in the formation of solid carbon or any material formulated to slow diffusion of the catalyst 106 to the underlying substrate 102. For example, the inert material 104 may be an oxide, a ceramic, a nitride, etc. In some embodiments, the inert material 104 may be alumina or silica. The inert material 104 may be selected such that the catalyst 106 has low diffusion into and is not reactive with the inert material 104 and has high surface mobility (i.e., surface diffusion).

The catalyst 106 may be deposited conformally over the inert material 104, such as by conventional thin-film deposition techniques (e.g., electroplating, coating, physical vapor deposition, chemical vapor deposition, etc.). The catalyst 106 may be any material formulated to promote the reaction of reaction gases to be used in the formation of CNTs and other fibrous carbon species. For example, some suitable catalysts are described in U.S. Patent Application Publication 2015/0078981, “Methods for Using Metal Catalysts in Carbon Oxide Catalytic Converters,” published Mar. 19, 2015; U.S. Patent Application Publication 2015/0086468, “Methods and Structures for Reducing Carbon Oxides with Non Ferrous Catalysts,” published Mar. 26, 2015; and U.S. Patent Application Publication 2016/0031710, “Carbon Oxide Reduction with Intermetallic and Carbide Catalysts,” published Feb. 4, 2016; the entire disclosure of each of which is hereby incorporated by reference.

For example, the catalyst 106 may include metals selected from groups 2 through 15 of the periodic table, such as from groups 5 through 10 (e.g., nickel, molybdenum, chromium, cobalt, tungsten, manganese, ruthenium, platinum, iridium, etc.), actinides, lanthanides, alloys thereof, and combinations thereof. Catalysts may include iron, nickel, cobalt, molybdenum, tungsten, chromium, and alloys thereof. Note that the periodic table may have various group numbering systems. As used herein, group 2 is the group including Be, group 3 is the group including Sc, group 4 is the group including Ti, group 5 is the group including V, group 6 is the group including Cr, group 7 is the group including Mn, group 8 is the group including Fe, group 9 is the group including Co, group 10 is the group including Ni, group 11 is the group including Cu, group 12 is the group including Zn, group 13 is the group including B, group 14 is the group including C, and group 15 is the group including N. CNTs form on materials such as on mild steel, 304 stainless steel, 316L stainless steel, steel wool, and 304 stainless steel wire. In some embodiments, the catalyst 106 is iron or an iron-containing material.

The catalyst 106 can be formed from catalyst precursors, selected to decompose to form the catalyst 106. The catalyst 106 may be prepared by combining precursors of the catalyst 106 with the inert material 104. Suitable precursors include compounds that combust or pyrolize to form oxides of the catalyst 106. For example, if iron is desired as the catalyst 106, some potential precursors include iron(III) nitrate, iron sulfite, iron sulfate, iron carbonate, iron acetate, iron citrate, iron gluconate, and iron oxalate. The metal loading on the inert material 104 may control the diameter of the solid carbon product ultimately formed.

After deposition, the catalyst 106 may then be processed to form nanoparticles 108 over the inert material 104. For example, the nanoparticles 108 may be discrete or nearly discrete particles of the catalyst 106 shown in FIG. 2A. In some embodiments, the nanoparticles 108 may be formed by heating the catalyst 106 in a reducing environment, such as in the presence of hydrogen. The reducing environment may activate the catalyst 106 by reducing metal oxides on the surface of the catalyst to provide a non-oxidized catalyst surface. In some embodiments, a gaseous feedstock used to form CNTs, such as methane, is used to reduce oxides from the catalyst. Catalyst reduction may occur prior to, or concurrent with, contacting the catalyst with the carbon-containing feedstock to make CNTs. The catalyst 106 may be heated to a temperature of at least about 550° C., at least about 600° C., at least about 650° C., at least about 700° C., or even at least about 750° C. Without being bound to any particular theory, it appears that heating in a reducing environment causes phenomena such as Ostwald ripening and subsurface diffusion. Such a theory is explained in, for example, Shunsuke Sakurai et al., “Role of Subsurface Diffusion and Ostwald Ripening in Catalyst Formation for Single-Walled Carbon Nanotube Forest Growth,” 134 J. AM. CHEM. SOC. 2148-2153 (2011), which is hereby incorporated by reference in its entirety. Through such processes, the catalyst 106 appears to rearrange to form the nanoparticles 108. Thus, catalyst material may be in the form of nanoparticles 108 of a selected dimension over the substrate 102. The distance between adjacent carbon particles or characteristic dimensions may be proportional to the diameter of the nanoparticles 108.

The nanoparticles 108 may be exposed to reaction gases to form nanostructured carbon 110 (e.g., CNTs or carbon nanofibers) on the nanoparticles 108, as shown in FIG. 2C. Nanostructured carbon 110 may form individually on each nanoparticle 108, such that each particle of nanostructured carbon 110 is discrete from adjacent particles of nanostructured carbon 110. That is, the nanoparticles 108 may individually act as distinct catalyst sites. The reaction rates may depend, in part, on the size and number of the nanoparticles 108, the reaction temperature, the reaction pressure, and the concentration of the reaction gases. Forming uniformly sized nanoparticles 108 may promote the uniformity of the nanostructured carbon 110 formed thereon, because the characteristics of nanostructured carbon 110 may depend on the size and/or shape of the nanoparticles 108.

The nanostructured carbon 110 is typically formed by a reaction between carbon monoxide and hydrogen:

CO+H₂↔HC₍ₛ₎+H₂O (Reaction 1).

The CO and H₂ are injected into a preheated reaction zone, typically preheated to a temperature at which the nanoparticles 108 are formed. The chemical composition, grain boundary, and grain size of the nanoparticles 108 typically affect the morphology of the resulting solid carbon products. Based on the stoichiometry of Reaction 1, the reaction gas mixture may include approximately one part CO to two parts hydrogen (stoichiometric amounts of reactants), or may include an excess of CO or H₂. For example, the reaction gas mixture may include between 1 and 10 parts H₂ to one part CO. In some embodiments, the reaction gas mixture includes between 1.6 and 8 parts H₂ to one part CO. Reaction 1 is exothermic, releasing 33.4 kcal/mol (1.16×10⁴ joules/gram of C₍ₛ₎) at 650° C. when CNTs are formed (i.e., ΔH=−33.4 kcal/mol). Reaction 1 may be used to efficiently produce solid carbon products of various morphologies on an industrial scale, using carbon monoxide (which may be derived, for example, from disproportionation of CO₂, from well gases, from combustion of hydrocarbons, etc.). Reaction 1 may proceed at temperatures from about 450° C. to over 2,000° C., depending on catalysts, pressures, etc.

In general, the reactions described herein proceed at a wide range of pressures, from near vacuum, to pressures of 4.0 MPa (580 psi) or higher. For example, solid carbon forms in pressure ranges from about atmospheric (0.1 MPa or 14.7 psi) to about 6.2 MPa (900 psi). In some embodiments, CNTs form at pressures from about 0.34 MPa (50 psi) to about 0.41 MPa (60 psi), at a pressure of about 4.1 MPa (600 psi), or even at pressure of about 0.5 MPa (75 psi) or less. Typically, increasing the pressure increases the reaction rate. In some embodiments, the pressure in a reaction vessel containing the substrate 102 with nanoparticles 108 thereon may be maintained at a pressure slightly above atmospheric (e.g., at a gauge pressure from about 7 kPa (1 psi) to about 69 kPa (10 psi).

Likewise, the reactions described herein proceed at a wide range of temperatures, such as from about 500° C. to about 1000° C., from about 550° C. to about 850° C., or from about 600° C. to about 800° C. The reaction rate is a function of temperature, and the characteristics of the solid carbon formed may vary based on the reaction rate. Thus, the reaction temperature may be selected such that CNTs form having selected properties (e.g., diameter, aspect ratio, etc.).

For example, carbon forests may be formed in a reaction between H₂ and CO when there is an excess of H₂ in the reaction gas. It appears that the reaction rate tends to increase with H₂ concentration until the H₂ concentration is about twice the CO concentration, after which additional H₂ slows the reaction.

In low pressure reactions (e.g., about 1.5 psi), carbon forests appear to grow uniformly and at high rates at temperatures between about 700° C. and 775° C. At such conditions, forest growth may typically continue for about an hour, with the highest growth rate about 30 minutes after the start of the reaction.

The reaction rates and height of carbon forests produced appear to increase approximately linearly with reaction pressure. The reaction temperature at which the reaction rates and heights of CNT forests produced appear to also increase with pressure at least up to about 95 psi. Carbon forest formed at 95 psi have been observed to be about 650 microns in height.

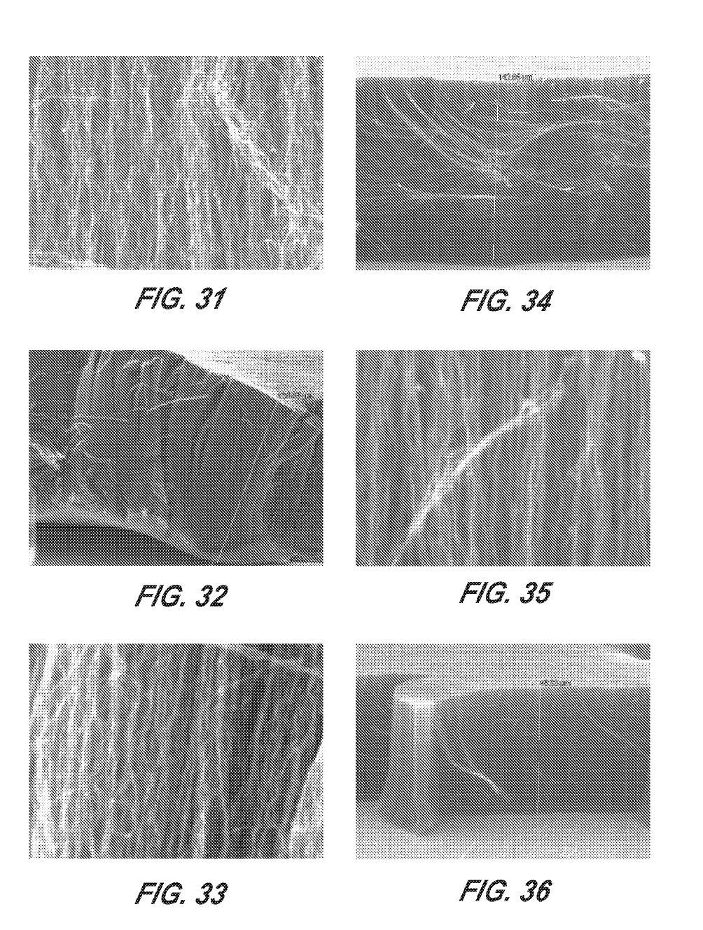

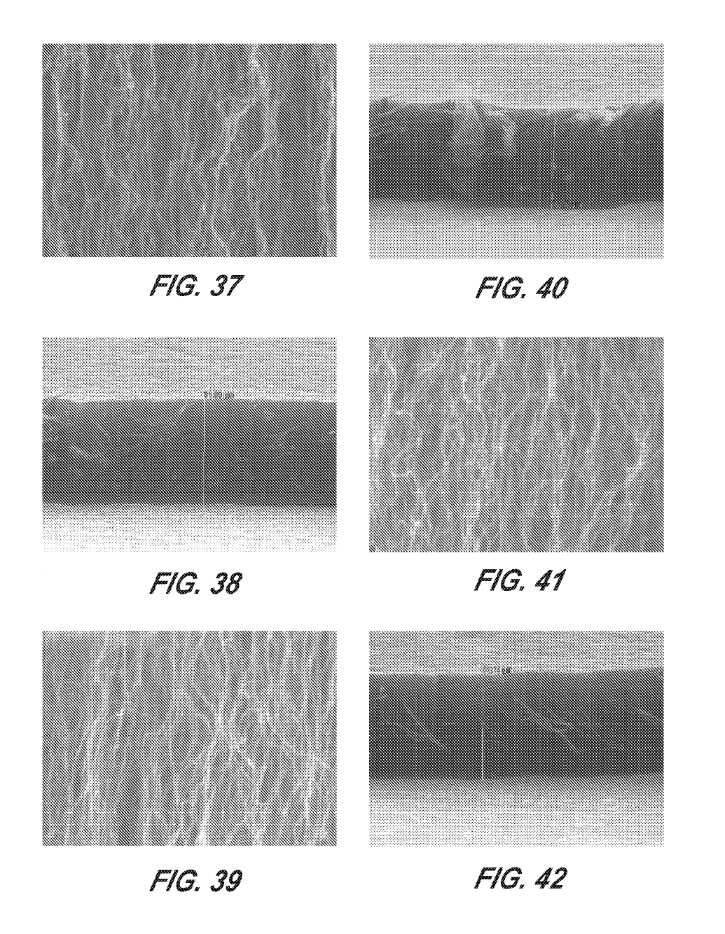

FIGS. 3A through 3C show a series of SEM (scanning electron microscope) images of a carbon forest of formed as described above. FIG. 3A, at about 500× magnification, shows fibers oriented generally parallel to one another and generally perpendicular to a substrate. Furthermore, the fibers in FIG. 3A are approximately of a uniform height (e.g., measured as a length from the substrate to the end of each fiber). FIG. 3B shows a portion of the same sample (roughly as indicated by area 3B in FIG. 3A) at about 10,000× magnification. At this higher magnification, the fibers still appear primarily parallel to one another. FIG. 3C shows a portion of the same sample (roughly as indicated by area 3C in FIG. 3B) at about 50,000× magnification. At this higher magnification, the fibers still appear primarily parallel to one another, but appear to have some variation in their orientation. For example, some fibers appear to have bends, and some even appear to bend 90° or more within the formation. Nevertheless, the fibers or portions thereof are generally parallel to one another.

The reaction of CO with H₂ to form solid carbon may be carried out in batch mode, continuous-flow mode, or a hybrid between batch and continuous flow. In continuous-flow mode, gases may or may not be recycled. If gases are recycled, the gases may pass through a condenser within each cycle or between cycles to remove excess water and to control the partial pressure of the water vapor in the reaction gas mixture. The partial pressure of water is one factor that appears to affect the type and character (e.g., morphology) of solid carbon formed, as well as the kinetics of carbon formation. Water vapor in the reaction gas mixture has two potentially deleterious effects: oxidation of catalyst, which stops carbon deposition; and the reaction of water with solid carbon (i.e., the reverse of Reaction 1) to form carbon monoxide and hydrogen, consuming the solid carbon product.

Carbon activity (A_{c}) can be used as an indicator of whether solid carbon will form under particular reaction conditions (e.g., temperature, pressure, reactants, concentrations). Without being bound to any particular theory, it is believed that carbon activity is the key metric for determining which allotrope of solid carbon is formed. Higher carbon activity tends to result in the formation of CNTs and nanofibers; lower carbon activity tends to result in the formation of graphitic forms.

Carbon activity for a reaction forming solid carbon from gaseous reactants can be defined as the reaction equilibrium constant times the partial pressure of gaseous products, divided by the partial pressure of reactants. For example, in the reaction, CO_{(g)}+H_{2(g)}⇄C₍ₛ₎+H₂O_{(g)}, with a reaction equilibrium constant of K, the carbon activity A_{c} is defined as K·(P_{CO}·P_{H2}/P_{H2O}). The carbon activity of this reaction may also be expressed in terms of mole fractions and total pressure: A_{c}=K·P_{T}(Y_{CO}·Y_{H2}/Y_{H2O}), where P_{T} is the total pressure and Y is the mole fraction of a species. Carbon activity generally varies with temperature because reaction equilibrium constants vary with temperature. Carbon activity also varies with total pressure for reactions in which a different number of moles of gas are produced than are consumed. Mixtures of solid carbon allotropes and morphologies thereof can be achieved by varying the catalyst and the carbon activity of the reaction gases in the reactor.

During reduction of carbon monoxide to form CNTs or nanofibers, such as in Reaction 1, above, each particle formed may raise a particle of catalyst material (e.g., a nanoparticle 108 or a portion thereof) from the surface of the inert material 104. Without being bound by any particular theory, it appears that the nanoparticles 108 are consumed by the formation of solid carbon, due to embedding nanoparticles 108 into growth tips of the solid carbon particles. The nanoparticles 108 may not be considered a catalyst in the classical sense, but are nonetheless referred to herein and in the art as a “catalyst,” because the carbon is not believed to react with the nanoparticles 108. Furthermore, some types of carbon may not form at all absent the nanoparticles 108.

A carbon forest may grow substantially perpendicular to the surface of the substrate 102, regardless of the contour or shape of the substrate 102. Consequently, carbon forests may form in many shapes and conformations by changing the shape or form of the substrate 102 underlying the nanoparticles 108.

The morphology of carbon formed may depend on the composition of the nanoparticles 108 and the way the nanoparticles 108 are formed. For example, carbon morphology may be related to size, shape, particle density (e.g., number of nanoparticles 108 per unit surface area), and arrangement of the nanoparticles 108. For example, the characteristic size of the nanoparticles 108 influences the characteristic diameter of fibers formed, and the particle density influences the density to which solid carbon forms.

Substances (e.g., sulfur) added to the reaction zone may act as catalyst promoters that accelerate the growth of carbon products. A catalyst promoter enhances the reaction rate by lowering the activation energy for the reaction on the promoted surface. Such promoters may be introduced into the reactor in a wide variety of compounds. Compounds may be selected such that the decomposition temperature of the compound is below the reaction temperature. For example, if sulfur is selected as a promoter for an iron-based catalyst, the sulfur may be introduced into the reaction zone as a thiophene gas, or as thiophene droplets in a carrier gas. Examples of sulfur-containing promoters include thiophene, hydrogen sulfide, heterocyclic sulfides, and inorganic sulfides. Other catalyst promoters include volatile lead (e.g., lead halides), bismuth compounds (e.g., volatile bismuth halides, such as bismuth chloride, bismuth bromide, bismuth iodide, etc.), ammonia, nitrogen, excess hydrogen (i.e., hydrogen in a concentration higher than stoichiometric), and combinations of these.

Heating catalyst structures in an inert carrier gas may cause the catalyst material to be in a form that promotes the growth of specific structures and morphologies, such as single-wall CNTs. For example, helium may promote the formation of a catalyst structure conducive to growth of different structures or morphologies of solid carbon.

The physical properties of the solid carbon products may be substantially modified by the application of additional substances to the surface of the solid carbon. Modifying agents (e.g., ammonia, thiophene, nitrogen gas, and/or surplus hydrogen) may be added to the reaction gases to modify the physical properties of the resulting solid carbon. Modifications and functionalizations may be performed in the reaction zone or after the solid carbon products have been removed.

Some modifying agents may be introduced into the reduction reaction chamber near the completion of the solid carbon formation reaction by, for example, injecting a water stream containing a substance to be deposited, such as a metal ion. A catalyst-modifying agent is a material that alters the size of metal clusters and alters the morphology of the carbon produced. Such substances may also be introduced as a component of a carrier gas. For example, surplus hydrogen appears to cause hydrogenation of a carbon lattice in some CNTs, causing the CNTs to have semiconductor properties.

Reaction temperatures depend on the composition or on the size of the nanoparticles 108. Nanoparticles 108 having small particle sizes tend to catalyze reactions at lower temperatures than the same materials having larger particle sizes. For example, Reaction 1 may occur at temperatures in the range of approximately 400° C. to 950° C., such as in the range of approximately 450° C. to 800° C., for iron-based catalysts, depending on the particle size and composition and the desired solid carbon product. In general, graphite and amorphous solid carbon form at lower temperatures, and CNTs and nanofibers form at higher temperatures.

A reactor may be configured to optimize the catalyst surface area exposed to reactant gases, thereby increasing reactor efficiency, carbon oxide reduction, and solid carbon product formation. Such reactors may be operated continuously, semi-continuously, or in batch mode. The catalyst and the solid carbon grown thereon are periodically removed from the reactor.

A reactor may be coupled with heating and cooling mechanisms to control the temperature of the reactor. For example, a reactor may be configured such that products and excess reactants are recycled through a cooling mechanism to condense water vapor. The products and/or excess reactant may then be reheated and recycled through the reactor. By removing some of the water vapor in the recycled gases, the morphology of solid carbon formed may be controlled. Changing the partial pressure of water vapor changes the carbon activity of a mixture. The reactor may also be coupled to a carbon collector in which water and unreacted reactants are separated from the carbon products. The separated carbon products are collected and removed from the system.

Reactors may be operated such that reactant flow is characterized by laminar flow to optimize the contact time between the catalyst and the reactants. In some embodiments, the carbon forest may undergo further processing on the substrate. For example, a relatively brief period or a relatively small region of turbulent flow may assist in removal of a carbon forest from the catalyst surface, if separation of a carbon forest is desired.

Reactors may be sized and configured to increase the exposed catalyst surface area per unit volume of reactor. For example, if the catalyst is disposed over a substrate, the substrate may be coiled in a spiral. Reactant gases may be distributed through a header or nozzle to direct the flow through the reactor. The reactant gas flow rate may be selected such that the reactant gases pass through the reactor in a laminar flow regime. If the catalyst is in a spiral formation, the gases may enter the reactor in the center of the catalyst spiral and exit the reactor at an outer wall of the reactor, such that approximately the entire catalyst surface is exposed to the reactant gases. In some embodiments for continuous processing, the inert material and catalyst material layers may be deposited on large sheets of stainless steel foil. A roll of this catalyst foil may be continuously fed through a furnace which has the appropriate environment for growing the carbon forest. The surface area of forest produced may vary based on the width of the foil and feed rate through the furnace.

In some embodiments, two or more reactors operate together such that the overall process is semi-continuous. In such embodiments, solid catalyst material is placed and secured in each reactor. Each reactor is configured to be selectively isolated from the process while other reactors are in process. For example, each reactor may be configured with gas supply lines, purge lines, reactor outlet lines, and a compressor. When sufficient solid carbon products have formed in one reactor to warrant removal, that reactor may be isolated from the system and taken offline, while another reactor is placed in operation. Solid carbon products are removed from the first reactor while solid carbon products are formed in the other reactor.

After the solid carbon product is removed from the first reactor, the first reactor is prepared to again form solid carbon products. When sufficient solid carbon product has been formed in the second reactor, the second reactor is isolated and taken offline. A third reactor may be operated while the solid carbon product is removed and collected from the second reactor. In some embodiments, if the first reactor is ready for the reaction when the second reactor is ready to be taken offline, the first reactor may be placed back online. In this manner, the process operates in a semi-continuous fashion, and at least one reactor prepares the catalyst surface while at least a second reactor is growing forest on the catalyst surface in the second reactor. Reactors may be operated as described in U.S. Patent Application Publication 2015/0291424, “Reactors and Methods for Producing Solid Carbon Materials,” published Oct. 15, 2015; U.S. Patent Application Publication 2016/0016800, “Reactors, Systems, and Methods for Forming Solid Products,” published Jan. 21, 2016; or U.S. Patent Application Publication 2016/0023902, “Systems for Producing Solid Carbon by Reducing Carbon Oxides,” published Oct. 15, 2015; the entire disclosure of each of which is hereby incorporated by reference.

In one embodiment, after a carbon forest has formed, the reaction gas mixture is removed from the reactor and replaced with a gas mixture for modifying or functionalizing the resulting carbon forest. The carbon oxide and the reducing agent are removed from the reactor, and a functionalizing gas mixture is introduced into the reactor. The functionalizing gas mixture may include functional groups such as alkyl groups, carbonyl groups, aromatics, non-aromatic rings, peptides, amino groups, hydroxyl groups, sulfate groups, or phosphate groups. The reaction temperature and pressure are maintained at suitable conditions for the functionalization of the carbon nanotubes to take place. In another embodiment, after the solid carbon product is formed, the reactor is cooled with inert gases, air, or other gases or functional groups.

Reaction 1, above, results in the formation of at least one solid carbon product and water. The water may subsequently be condensed. Latent heat of the water may be extracted for heating purposes or as part of a low-pressure power extraction cycle. The water may be a useful co-product used for another process.

The methods disclosed herein may be incorporated into power production, chemical processes, and manufacturing processes in which the combustion of a primary hydrocarbon fuel source is the primary source of heat. The resulting combustion gases from such processes may contain carbon monoxide (and/or carbon dioxide, which may be converted to carbon monoxide) that may act as a source of carbon for the manufacture of the desired solid carbon product. The methods are scalable for many different production capacities so that, for example, plants designed to use this method may be sized to handle emissions from the combustion processes of a large coal-fired power plant or those from an internal combustion engine. For example, the methods may be used to reduce carbon oxides from the atmosphere, combustion gases, process off-gases, exhaust gases from the manufacture of Portland cement, and well gases, or from separated fractions thereof.

In another embodiment, carbon oxides from a source gas mixture are separated from a source mixture and concentrated to form the carbon oxide feedstock for the reduction process. The carbon oxides in the source gases may be concentrated through various means known in the art (e.g., amine absorption and regeneration). In yet another embodiment, the catalytic conversion process may be employed as an intermediate step in a multi-stage power extraction process wherein the first stages cool the combustion gases to the reaction temperature of the reduction process for the formation of the desired solid carbon product. The cooled combustion gases, at the desired temperature of the reduction reaction, may then be passed through the reduction process and subsequently passed through additional power extraction stages. Coupling this method with a hydrocarbon combustion process for electrical power production has an additional advantage in that the hydrogen required for the reduction process may be formed by the electrolysis of water using off-peak power.

In some cases, it may be beneficial to remove the solid carbon product from the reaction gas mixture prior to cooling (e.g., by withdrawing the solid carbon product from the reactor through a purge chamber wherein the reaction gases are displaced by an inert purging gas such as argon, nitrogen, or helium). Purging prior to cooling helps reduce the deposit or growth of undesirable morphologies on the desired solid carbon product during the cooling process.

### EXAMPLES

The following examples illustrate the processes described. Each example is explained in additional detail in the following subsection, and scanning electron microscope images of the products of each of the examples are included.

For Examples 1-11, below, substrates were cut from a sheet of 304 stainless steel having a thickness of approximately 0.15 mm (0.006 in). Each substrate was approximately 13 mm wide and approximately 18 mm to 22 mm long. One surface of each substrate was coated with an inert barrier material, and the inert barrier material was coated with catalyst. The coated substrates were separately placed in quartz boats about 8.5 cm long and 1.5 cm wide, and the boats were inserted lengthwise into a quartz tube having an inner diameter of about 2.54 cm and a length of about 1.2 m. The quartz tube was placed in a stainless steel pipe, which was then placed in a tube furnace. The stainless steel pipe was purged with hydrogen gas before the tube furnace was heated to operating conditions. After the tube furnace reached operating conditions, reaction gases were introduced into the quartz tube (i.e., flowed continuously through the quartz tube) such that both the upper and lower surfaces of each substrate were exposed to reaction gas. After the test, the substrates were removed and examined.

### Example 1

One surface of each of three stainless steel substrates was coated with a barrier of Al₂O₃ having a thickness of approximately 40 nm using an electron-beam evaporator (available from Denton Vacuum, of Moorestown, N.J.). The Al₂O₃ was then coated with iron having a thickness of approximately 6 nm using a thermal evaporator (model CHA-600, available from CHA Industries, of Fremont, Calif.).

The three substrates were placed in a quartz tube in a stainless steel pipe as described above. The stainless steel pipe was heated in the tube furnace to 700° C. while H₂ flowed through the quartz tube. Once the pipe reached 700° C., the pipe with the quartz tube and substrates therein was cooled to an approximately uniform temperature of 600° C.

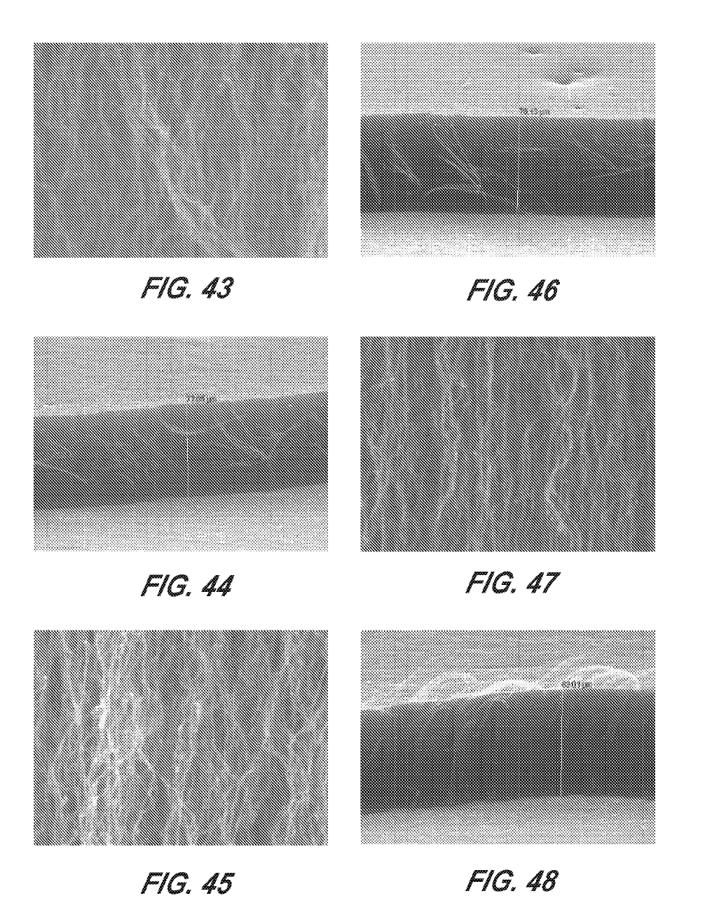

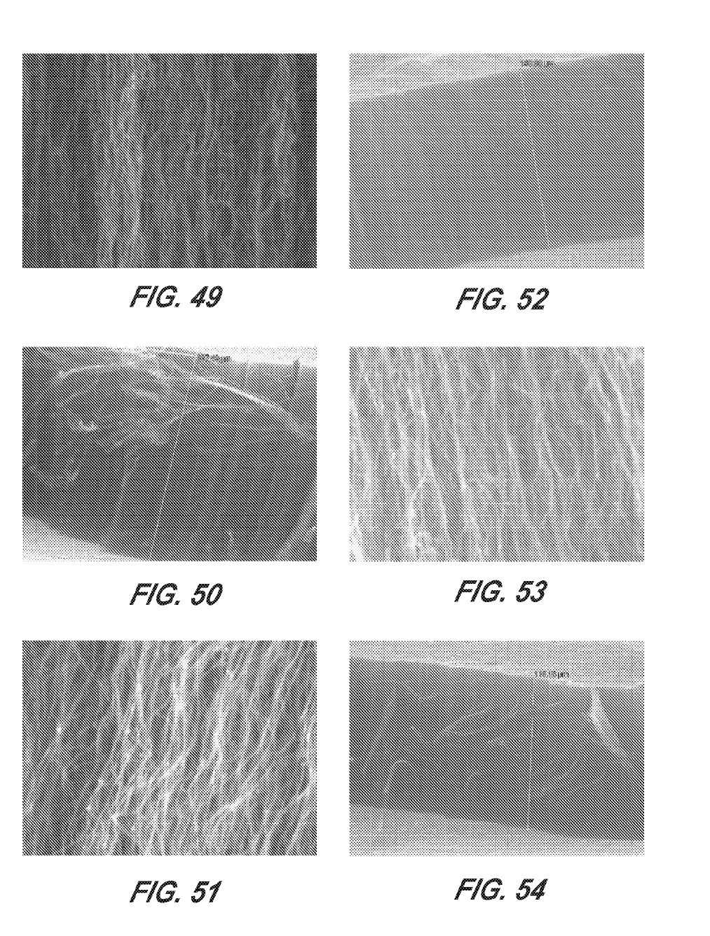

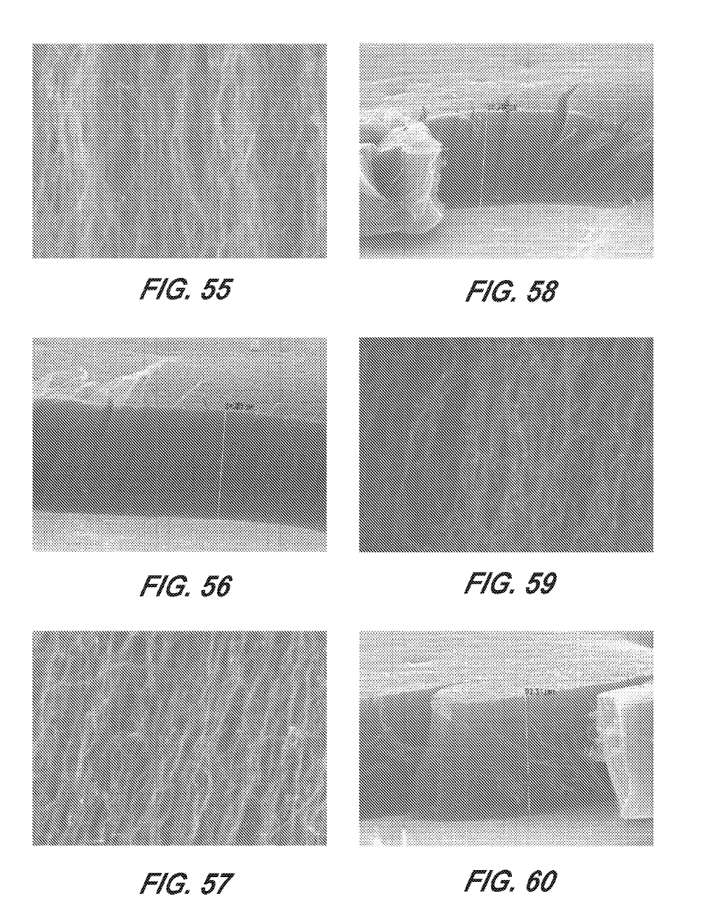

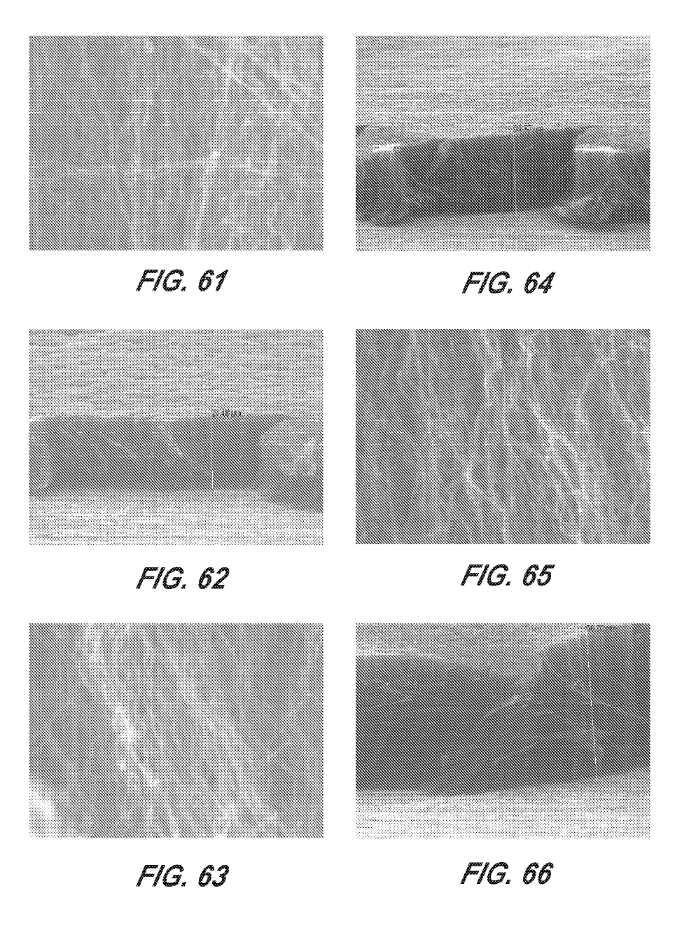

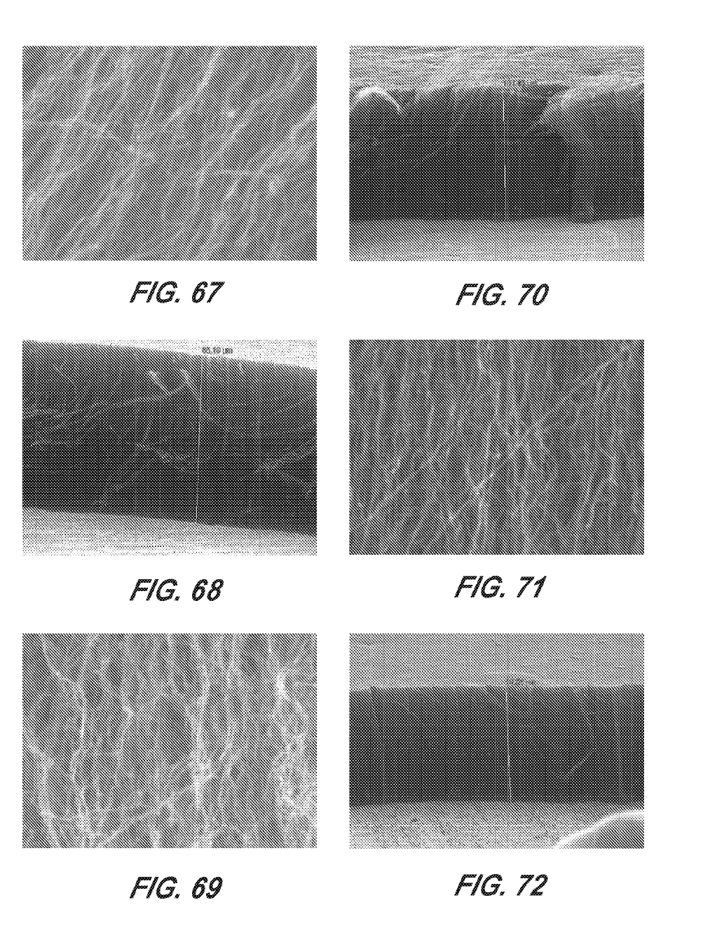

A reaction gas containing about 45% H₂, 45% CO, and 10% Ar was introduced into the quartz tube at a gauge pressure of about 7 kPa (1 psi) (i.e., an absolute pressure of about 7 kPa above atmospheric pressure). The gas flowed over the substrates for about 60 minutes at 800 sccm (standard cubic centimeters per minute). After the reaction, Ar flowed through the quartz tube and over the substrates until they cooled to room temperature. Solid carbon formed on the coated surfaces of each of the substrates, but not on the uncoated surfaces of the substrates. Samples of the solid carbon were imaged using SEM, as shown in FIGS. 4 through 6 at about 5,000× magnification.

The SEM images show a mass of CNTs and/or nanofibers appearing as a tangled mat on the surface of the substrates. These growth conditions produced solid carbon at relatively slow rates.

TABLE 1
Solid Carbon Formation over iron-coated
Al₂O₃ in 45% H₂, 45% CO, and 10% Ar

| | Sample # | | |
|---|---|---|---|
| | 1 | 2 | 3 |
| Distance from inlet (inches) | 22.25 | 25.75 | 29.25 |
| (centimeters) | 56.515 | 65.405 | 74.295 |
| Temperature (° C.) | 600 | 600 | 600 |
| SEM image | FIG. 4 | FIG. 5 | FIG. 6 |

### Example 2

Three substrates were prepared, placed in a quartz tube in a stainless steel pipe, preheated to 700° C., and cooled to 600° C. as described in Example 1. A reaction gas containing about 45% H₂, 45% CO, and 10% Ar was introduced into the quartz tube at a gauge pressure of about 0.31 MPa (45 psi). The gas flowed over the substrates for about 60 minutes at 800 sccm. After the reaction, Ar flowed through the quartz tube and over the substrates until they cooled to room temperature. Solid carbon formed on the coated surfaces of each of the substrates, but not on the uncoated surfaces of the substrates. Inlet and outlet gas compositions were measured by mass spectrometry, and reported in Table 2, below. Samples of the solid carbon were imaged using SEM, as shown in FIGS. 7 through 9 at about 5,000× magnification.

The SEM images show a mass of CNTs and/or nanofibers appearing as a tangled mat on the surface of the substrates. These growth conditions produced solid carbon at relatively slow rates.

TABLE 2
Solid Carbon Formation over iron-coated
Al₂O₃ in 45% H₂, 45% CO, and 10% Ar

| | | Sample # | | | |
|---|---|---|---|---|---|
| | Inlet | 1 | 2 | 3 | Outlet |
| Distance from inlet (inches) | | 22.5 | 25.75 | 29.5 | |
| (centimeters) | | 57.15 | 65.405 | 74.93 | |
| Temperature (° C.) | | 600 | 600 | 600 | |
| H₂ composition (%) | 44.63 | | | | 44.72 |
| CH₄ composition (%) | 0.03 | | | | 0.04 |
| CO composition (%) | 46.35 | | | | 46.21 |
| CO₂ composition (%) | 0.17 | | | | 0.17 |
| Ar composition (%) | 8.83 | | | | 8.86 |
| SEM image | | FIG. 7 | FIG. 8 | FIG. 9 | |

### Example 3

Three substrates were prepared and placed in a quartz tube in a stainless steel pipe, as described in Example 1. The stainless steel pipe was heated in the tube furnace to 750° C. while H₂ flowed through the quartz tube. Once the stainless steel pipe reached 750° C., the stainless steel pipe with the substrates therein was maintained at 750° C. A reaction gas containing about 90% CO and 10% Ar was introduced into the quartz tube at a gauge pressure of about 7 kPa (1 psi). The gas flowed over the substrates for about 60 minutes at 800 sccm. After the reaction, Ar flowed through the quartz tube and over the substrates until they cooled to room temperature. No solid carbon growth was observed on the coated surfaces or the uncoated surfaces of the substrates. Inlet and outlet gas compositions were measured by mass spectrometry, as reported in Table 3, below.

TABLE 3
Gas Compositions in Example 3

| | Inlet | Outlet |
|---|---|---|
| H₂ composition (%) | 2.29 | 2.45 |
| CH₄ composition (%) | 0.03 | 0.05 |
| CO composition (%) | 89.54 | 89.36 |
| CO₂ composition (%) | 0.09 | 0.14 |
| Ar composition (%) | 8.05 | 7.99 |

### Example 4

Six substrates were prepared and placed in a quartz tube in a stainless steel pipe, as described in Example 1. The stainless steel pipe was heated in the tube furnace to 500° C. while Ar flowed through the quartz tube. The flow of Ar was terminated, and a flow of H₂ was begun. The stainless steel pipe was further heated in the tube furnace while H₂ flowed through the quartz tube. A temperature gradient formed along the stainless steel pipe and along the quartz tube therein. Once the inlet of the quartz tube reached 500° C. and the outlet of the quartz tube reached 800° C., a reaction gas containing about 45% H₂, 45% CO, and 10% Ar was introduced into the quartz tube at a gauge pressure of about 7 kPa (1 psi). The gas flowed over the substrates for about 30 minutes at 800 sccm. After the reaction, Ar flowed through the quartz tube and over the substrates until they cooled to room temperature. Solid carbon formed on the coated surfaces of each of the six substrates, but not on the uncoated surfaces of the substrates. Inlet and outlet gas compositions were measured by mass spectrometry, as reported in Table 4, below. Two samples (#4 and #5) of the solid carbon were imaged using SEM, as shown in FIGS. 10 and 11 at about 5,000× magnification, and one sample (#6) was imaged, as shown in FIGS. 12 and 13, at about 500× and about 50,000×, respectively. The SEM image of sample #6 showed a uniform forest of solid carbon approximately 20 nm in diameter and approximately 142 μm tall. Samples #4, #5, and #6 were selected for SEM imaging because they appeared to have the most forest-like formation of solid carbon.

The SEM images in FIGS. 10 and 11 show a mass of CNTs and/or nanofibers appearing as a tangled mat on the surface of the substrates. These growth conditions produced solid carbon at relatively slow rates.

FIGS. 12 and 13 show SEM images of carbon forests at 730° C., the highest temperature tested in Example 4. This appears to indicate that the reason forests were not formed in the previous tests was that the temperature was too low. FIG. 13 shows the carbon forest wall at higher magnification than FIG. 12, and indicates that the structure shown in FIG. 12 includes CNTs and/or nanofibers.

TABLE 4
Solid Carbon Formation over iron-coated Al₂O₃ in 45% H₂, 45% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.25 | 18.75 | 22.0 | 25.75 | 29.25 | 32.75 | |
| (centimeters) | | 38.735 | 47.625 | 55.88 | 65.405 | 74.295 | 83.185 | |
| Temperature (° C.) | | 544 | 585 | 633 | 663 | 690 | 730 | |
| H₂ composition (%) | 47.19 | | | | | | | 46.64 |
| CH₄ composition (%) | 0.00 | | | | | | | 0.00 |
| CO composition (%) | 42.74 | | | | | | | 43.12 |
| CO₂ composition (%) | 0.03 | | | | | | | 0.02 |
| Ar composition (%) | 10.06 | | | | | | | 10.23 |
| SEM image | | | | | FIG. 10 | FIG. 11 | FIG. 12 | |
| | | | | | | | FIG. 13 | |

### Example 5

The experiment described in Example 4 was repeated. Solid carbon formed on the coated surfaces of each of the six substrates, but not on the uncoated surfaces of the substrates. Inlet and outlet gas compositions were measured by mass spectrometry, as reported in Table 5, below. Samples #3 and #4 of the solid carbon were imaged using SEM at about 10,000× magnification, as shown in FIGS. 14 and 15. Sample #5 was imaged at about 10,000× and about 50,000×, as shown in FIGS. 16 and 17, respectively. Sample #6 was imaged at about 1,000× and about 50,000×, as shown in FIGS. 18 and 19, respectively. Samples #3, #4, #5, and #6 were selected for SEM imaging because they appeared to have the most forest-like formation of solid carbon.

The SEM images in FIGS. 14 and 15 show a mass of CNTs and/or nanofibers appearing as a tangled mat on the surface of the substrates. These growth conditions produced solid carbon at relatively slow rates. Based on the results of Example 4, it appears that carbon forests did not form because the reaction temperature was too low.

FIGS. 16 and 17 show growth of a short carbon forest. As substrate at a similar temperature, pressure, and composition in Example 4 did not form carbon forests, indicating that 690° C. may be near the lower limit for carbon forest growth with this composition and gas pressure.

FIGS. 18 and 19: show SEM images of carbon forests formed at 737° C. FIG. 19 shows the carbon forest wall at higher magnification than FIG. 18, and indicates that the structure shown in FIG. 18 includes CNTs and/or nanofibers. The carbon forest is slightly shorter than the carbon forest shown in FIG. 12, indicating the growth rate was slightly lower.

TABLE 5
Solid Carbon Formation over iron-coated Al₂O₃ in 45% H₂, 45% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.5 | 18.75 | 22 | 25.75 | 29.5 | 33.25 | |
| (centimeters) | | 39.37 | 47.625 | 55.88 | 65.405 | 74.93 | 84.455 | |
| Temperature (° C.) | | 547 | 585 | 632 | 663 | 691 | 737 | |
| H₂ composition (%) | 43.41 | | | | | | | 43.45 |
| CH₄ composition (%) | 0.00 | | | | | | | 0.00 |
| CO composition (%) | 47.43 | | | | | | | 47.51 |
| CO₂ composition (%) | 0.04 | | | | | | | 0.02 |
| Ar composition (%) | 9.13 | | | | | | | 9.02 |
| SEM image | | | | FIG. 14 | FIG. 15 | FIG. 16 | FIG. 18 | |
| | | | | | | FIG. 17 | FIG. 19 | |

### Example 6

Six substrates were prepared and placed in a quartz tube in a stainless steel pipe, as described in Example 1. The stainless steel pipe was heated until a temperature gradient formed along the stainless steel pipe such that the inlet of the quartz tube in the tube furnace reached 500° C. and the outlet of the quartz tube reached 800° C. while H₂ flowed through the quartz tube. Once the reaction temperature profile was reached, a reaction gas containing about 55% H₂, 35% CO, and 10% Ar was introduced into the quartz tube at about 0.11 MPa (15.7 psi). The gases flowed over the substrates for about 30 minutes at 800 sccm. After the reaction, Ar flowed through the quartz tube and over the substrates until they cooled to room temperature. Solid carbon formed on the coated surfaces of each of the six substrates, but not on the uncoated surfaces of the substrates. Inlet and outlet gas compositions were measured by mass spectrometry, as reported in Table 6, below. Sample #3 of the solid carbon was imaged using SEM at about 10,000× magnification, as shown in FIG. 20. Samples #4, #5, and #6 were each imaged at about 1,000× and about 50,000×, as shown in FIGS. 21 through 26. Samples #3, #4, #5, and #6 were selected for SEM imaging because they appeared to have the most forest-like formation of solid carbon.

FIGS. 20 through 26 show that a higher temperature range produces more consistent carbon forest growth than, for example, the samples in Examples 4 and 5. The height of the carbon forests increases between the sample at 715° C. and 742° C. and then decreases again for the sample at 797° C. Thus, there appears to be a temperature that produces a local maximum growth rate for this pressure and gas composition somewhere near 742° C.

TABLE 6
Solid Carbon Formation over iron-coated Al₂O₃ in 55% H₂, 35% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.5 | 19 | 23 | 26.5 | 29.5 | 34 | |
| (centimeters) | | 39.37 | 48.26 | 58.42 | 67.31 | 74.93 | 86.36 | |
| Temperature (° C.) | | 597 | 642 | 692 | 718 | 742 | 797 | |
| H₂ composition (%) | 57.37 | | | | | | | 57.88 |
| CH₄ composition (%) | 0.00 | | | | | | | 0.00 |
| CO composition (%) | 33.58 | | | | | | | 33.28 |
| CO₂ composition (%) | 0.03 | | | | | | | 0.04 |
| Ar composition (%) | 9.03 | | | | | | | 8.81 |
| SEM image | | | | FIG. 20 | FIG. 21 | FIG. 23 | FIG. 25 | |
| | | | | | FIG. 22 | FIG. 24 | FIG. 26 | |

### Example 7

The experiment described in Example 6 was repeated, but with a reaction gas containing about 70% H₂, 20% CO, and 10% Ar. Solid carbon formed on the coated surfaces of each of the six substrates, but not on the uncoated surfaces of the substrates. Inlet and outlet gas compositions were measured by mass spectrometry, as reported in Table 7, below. Sample #2 of the solid carbon was imaged using SEM at about 5,000× magnification, as shown in FIG. 27. Samples #3, #4, #5, and #6 were each imaged at about 500× and about 50,000×, as shown in FIGS. 28 through 35. Samples #2, #3, #4, #5, and #6 were selected for SEM imaging because they appeared to have the most forest-like formation of solid carbon.

FIGS. 27 through 35 appear to shows that gas compositions containing an excess of hydrogen gas increase the reaction rate in comparison with Example 6. An excess of hydrogen may also prolong catalyst activity.

TABLE 7
Solid Carbon Formation over iron-coated Al₂O₃ in 70% H₂, 20% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.5 | 19.25 | 22.75 | 26.25 | 29.5 | 33.5 | |
| (centimeters) | | 39.37 | 48.895 | 57.786 | 66.675 | 74.93 | 85.09 | |
| Temperature (° C.) | | 596 | 643 | 689 | 717 | 742 | 789 | |
| H₂ composition (%) | 69.88 | | | | | | | 70.37 |
| CH₄ composition (%) | 0.00 | | | | | | | 0.00 |
| CO composition (%) | 19.37 | | | | | | | 19.15 |
| CO₂ composition (%) | 0.02 | | | | | | | 0.03 |
| Ar composition (%) | 10.37 | | | | | | | 10.40 |
| SEM images | | | FIG. 27 | FIG. 28 | FIG. 30 | FIG. 32 | FIG. 34 | |
| | | | | FIG. 29 | FIG. 31 | FIG. 33 | FIG. 35 | |

### Example 8

The experiment described in Example 6 was repeated, but with a reaction gas containing about 80% H₂, 10% CO, and 10% Ar. Solid carbon formed on the coated surfaces of each of the six substrates, but not on the uncoated surfaces of the substrates. Inlet and outlet gas compositions were measured by mass spectrometry, as reported in Table 8, below. Sample #5 of the solid carbon was imaged using SEM at about 1,000× and about 50,000×, as shown in FIGS. 36 and 37. No similar structures were observed on samples #1 through #4 or #6.

This Example shows that carbon forest growth is diminished when the hydrogen composition is too high. Thus, there may be a maximum growth rate corresponding to a hydrogen composition below 80%.

TABLE 8
Solid Carbon Formation over iron-coated Al₂O₃ in 80% H₂, 10% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.0 | 19.0 | 22.0 | 25.5 | 30.0 | 32.75 | |
| (centimeters) | | 38.1 | 48.26 | 55.88 | 64.77 | 76.2 | 83.185 | |
| Temperature (° C.) | | 589 | 639 | 700 | 711 | 746 | 779 | |
| H₂ composition (%) | 80.05 | | | | | | | 80.05 |
| CH₄ composition (%) | 0.00 | | | | | | | 0.00 |
| CO composition (%) | 10.78 | | | | | | | 10.74 |
| CO₂ composition (%) | 0.01 | | | | | | | 0.01 |
| Ar composition (%) | 9.18 | | | | | | | 9.21 |
| SEM images | | | | | | FIG. 36 | | |
| | | | | | | FIG. 37 | | |

### Example 9

The experiment described in Example 7 was repeated with the entire length of the quartz tube held at a reaction temperature of about 750° C. Solid carbon formed on the coated surfaces of each of the six substrates, but not on the uncoated surfaces of the substrates. Inlet and outlet gas compositions were measured by mass spectrometry, as reported in Table 9, below. Samples #1 through #6 of the solid carbon were imaged using SEM at about 500× and about 50,000×, as shown in FIGS. 38 through 49.

FIGS. 38 through 49 show consistent carbon forest height, indicating effective parameters to grow carbon forests consistently and near the tallest height and fastest rate tested so far.

TABLE 9
Solid Carbon Formation over iron-coated Al₂O₃ in 70% H₂, 20% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 14.75 | 18.75 | 22 | 25.5 | 29 | 32.5 | |
| (centimeters) | | 37.465 | 47.625 | 55.88 | 64.77 | 73.66 | 82.55 | |
| Temperature (° C.) | | 781 | 762 | 752 | 746 | 746 | 749 | |
| H₂ composition (%) | 68.26 | | | | | | | 69.19 |
| CH₄ composition (%) | 0.00 | | | | | | | 0.00 |
| CO composition (%) | 22.12 | | | | | | | 21.57 |
| CO₂ composition (%) | 0.03 | | | | | | | 0.03 |
| Ar composition (%) | 9.60 | | | | | | | 9.22 |
| SEM image | | FIG. 38 | FIG. 40 | FIG. 42 | FIG. 44 | FIG. 46 | FIG. 48 | |
| | | FIG. 39 | FIG. 41 | FIG. 43 | FIG. 45 | FIG. 47 | FIG. 49 | |

### Example 10

The experiment described in Example 9 was repeated at a gauge pressure of about 69 kPa (10 psi). Solid carbon formed on the coated surfaces of each of the six substrates, but not on the uncoated surfaces of the substrates. Inlet and outlet gas compositions were measured by mass spectrometry, as reported in Table 10, below. Samples #1 through #6 of the solid carbon were imaged using SEM at about 500× and about 50,000×, as shown in FIGS. 50 through 61.

FIGS. 50 through 61 show that the average carbon forest height increased from Example 9. The carbon forest height was not as consistent across all samples as in Example 9, but the overall average height and average forest growth rate increases with increasing pressure.

TABLE 10
Solid Carbon Formation over iron-coated Al₂O₃ in 70% H₂, 20% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.5 | 18.75 | 22.25 | 25.75 | 29.25 | 32.5 | |
| (centimeters) | | 39.37 | 47.625 | 56.515 | 65.405 | 74.295 | 82.55 | |
| Temperature (° C.) | | 750 | 750 | 750 | 750 | 750 | 750 | |
| H₂ composition (%) | 65.9 | | | | | | | 65.85 |
| CH₄ composition (%) | 0.0 | | | | | | | 0.0 |
| CO composition (%) | 25.14 | | | | | | | 25.11 |
| CO₂ composition (%) | 0.04 | | | | | | | 0.04 |
| Ar composition (%) | 8.93 | | | | | | | 9.00 |
| SEM image | | FIG. 50 | FIG. 52 | FIG. 54 | FIG. 56 | FIG. 58 | FIG. 60 | |
| | | FIG. 51 | FIG. 53 | FIG. 55 | FIG. 57 | FIG. 59 | FIG. 61 | |

### Example 11

The experiment described in Example 6 was repeated, but with a reaction gas containing about 60% H₂, 30% CO, and 10% Ar and with the entire length of the quartz tube held at a reaction temperature of about 750° C. Solid carbon formed on the coated surfaces of each of the six substrates, but not on the uncoated surfaces of the substrates. Inlet and outlet gas compositions were measured by mass spectrometry, as reported in Table 11, below. Samples #1 through #4 of the solid carbon were imaged using SEM at about 1,000× and about 50,000×, as shown in FIGS. 62 through 69. Samples #5 and #6 were imaged using SEM at about 500× and about 50,000×, as shown in FIGS. 70 through 73.

FIGS. 62 through 73 show that a slightly lower concentration of hydrogen in comparison with Example 9 may produce taller carbon forests.

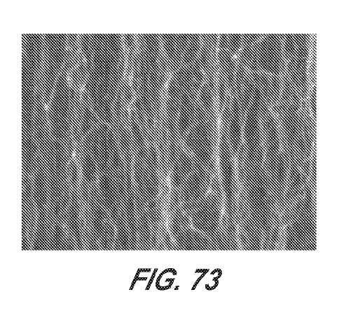

TABLE 11
Solid Carbon Formation over iron-coated Al₂O₃ in 60% H₂, 30% CO, and 10% Ar

| | | Sample # | | | | | | |
|---|---|---|---|---|---|---|---|---|
| | Inlet | 1 | 2 | 3 | 4 | 5 | 6 | Outlet |
| Distance from inlet (inches) | | 15.25 | 18.75 | 22 | 25.75 | 29.25 | 32.75 | |
| (centimeters) | | 38.735 | 47.625 | 55.88 | 65.405 | 74.295 | 83.185 | |
| Temperature (° C.) | | 780 | 762 | 752 | 745 | 747 | 749 | |
| H₂ composition (%) | 60.88 | | | | | | | 61.80 |
| CH₄ composition (%) | 0.0 | | | | | | | 0.0 |
| CO composition (%) | 28.97 | | | | | | | 28.29 |
| CO₂ composition (%) | 0.03 | | | | | | | 0.02 |
| Ar composition (%) | 10.21 | | | | | | | 9.92 |
| SEM image | | FIG. 62 | FIG. 64 | FIG. 66 | FIG. 68 | FIG. 70 | FIG. 72 | |
| | | FIG. 63 | FIG. 65 | FIG. 67 | FIG. 69 | FIG. 71 | FIG. 73 | |

1. A method of producing forests of fibrous solid carbon, the method comprising:
providing a catalyst material over a substrate;
forming catalyst nanoparticles from the catalyst material; and
reacting carbon monoxide with hydrogen in the presence of the catalyst nanoparticles to form forests of fibrous solid carbon attached to the catalyst nanoparticles.

2. The method of claim 1, further comprising providing an inert material over the substrate.

3. The method of claim 2, wherein providing an inert material over a substrate comprises depositing the inert material directly on the substrate.

4. The method of claim 2, wherein providing an inert material over the substrate comprises providing an oxide, a ceramic, and/or a nitride over the substrate.

5. The method of claim 2, wherein providing an inert material over the substrate comprises providing a material selected from the group consisting of alumina and silica.

6-7. (canceled)

8. The method of claim 1 wherein providing a catalyst material over a substrate comprises providing at least one metal selected from groups 2 through 15 of the periodic table over the substrate.

9. The method of claim 8, wherein providing at least one metal selected from groups 2 through 15 of the periodic table over the substrate comprises providing iron over the substrate.

10. (canceled)

11. The method of claim 1 wherein providing a catalyst material over a substrate comprises providing the catalyst material over a stainless steel substrate.

12. The method of claim 1 wherein forming catalyst nanoparticles comprises heating the catalyst material in a reducing environment.

13. (canceled)

14. The method of claim 12, wherein heating the catalyst material in a reducing environment comprises heating the catalyst material in the presence of hydrogen.

15. (canceled)

16. The method of claim 1, wherein reacting carbon monoxide with hydrogen in the presence of the catalyst nanoparticles comprises forming water, and further comprising removing at least a portion of the water from the presence of the catalyst material while reacting the carbon monoxide with hydrogen.

17. The method of claim 1 wherein reacting carbon monoxide with hydrogen in the presence of the catalyst nanoparticles comprises reacting the carbon monoxide with hydrogen at a temperature in range from about 600° C. to about 1000° C.

18. The method of claim 1 wherein reacting carbon monoxide with hydrogen in the presence of the catalyst nanoparticles comprises reacting the carbon monoxide with hydrogen at a pressure of about 0.5 MPa or less.

19. A composition of matter comprising:
an inert material on a substrate;
a plurality of catalyst nanoparticles over the inert material; and
a plurality of particles of fibrous solid carbon, wherein each particle of the fibrous solid carbon is attached to a nanoparticle of the plurality of catalyst nanoparticles.

20. The composition of claim 19, wherein the inert material comprises at least one material selected from the group consisting of alumina and silica.

21. The composition of claim 19 wherein the inert material forms a physical barrier between the plurality of catalyst nanoparticles and the substrate.

22. A method comprising:
depositing an inert material onto a stainless steel sheet;
depositing iron onto the inert material;
heating the stainless steel sheet with the inert material and the iron thereon in a furnace chamber; and
providing a mixture of hydrogen and carbon monoxide into the furnace chamber to form a forest of fibrous carbon nanoparticles on the iron.

23. The method of claim 22, wherein providing a mixture of hydrogen and carbon monoxide into the furnace chamber comprises providing a mixture of hydrogen and carbon monoxide into the furnace chamber at a pressure above atmospheric pressure.

24. (canceled)

25. The method of claim 22, wherein heating the stainless steel sheet comprises rearranging atoms of the deposited iron to form iron nanoparticles on the inert material.

26. The method of claim 22, wherein providing a mixture of hydrogen and carbon monoxide comprises providing a mixture of hydrogen and carbon monoxide at a ratio between about 1.6:1 and 8:1.

27-29. (canceled)
